(19) United States
(12) Patent Application Publication
(10) Pub. No.: US 2009/0032922 A1
(43) Pub. Date: Feb. 5, 2009

(54) Semiconductor Package, Printed Wiring Board Structure and Electronic Apparatus

(75) Inventor: Yuichi Koga, Hachioji-shi (JP)

Correspondence Address: BLAKELY SOKOLOFF TAYLOR & ZAFMAN LLP, 1279 OAKMEAD PARKWAY, SUNNYVALE, CA, 94085-4040, US

(73) Assignee: KABUSHIKI KAISHA TOSHIBA, Tokyo (JP)

(21) Appl. No.: 12/182,034

(22) Filed: Jul. 29, 2008

(30) Foreign Application Priority Data
Jul. 31, 2007 (JP) 2007-199342

(51) Int. Cl. H01L 23/495

(52) U.S. Cl. 257/676; 257/E23.031

(57) ABSTRACT

According to one embodiment, a semiconductor package comprises a substrate having one surface mounted with a semiconductor chip, and the other surface mounted with a plurality of arrayed external connection electrodes, a differential line pair provided on the surface of the substrate mounted with the semiconductor chip, and making a connection between the semiconductor chip and a predetermined pair of electrodes included in the external connection electrodes, and a coupling capacitor pair inserted between the differential lines.

### CROSS-REFERENCE TO RELATED APPLICATIONS

This application is based upon and claims the benefit of priority from Japanese Patent Application No. 2007-199342, filed Jul. 31, 2007, the entire contents of which are incorporated herein by reference.

### BACKGROUND

1. Field

One embodiment of the present invention relates to a semiconductor package handling a differential signal and an electronic apparatus mounted with the semiconductor package.

2. Description of the Related Art

In an electronic apparatus such as personal computer, a circuit board is received as a main constituent component in a body of the electronic apparatus. The circuit board is mounted with a semiconductor device called as a chip set forming a CPU and peripheral circuits for the CPU.

This kind of the circuit board mounted with the semiconductor device requires high density wiring and high density mounting to achieve high speed signal processing and high performance. In order to meet the foregoing requirements, a high-density mounting technique has been proposed. According to the technique, one main surface of a multi-layer stacked board is mounted with an integrated circuit, and the other main surface thereof is mounted with a BGA (ball grid array) component. See Jpn. Pat. Appln. KOKAI Publication No. 2003-101432, for example.

A high-speed bus interface using a differential signal is applied as a technique for achieving high speed processing. The high-speed bus interface using the differential signal is provided with a coupling capacitor between an input circuit device and an output circuit device for preventing a direct current component from flowing between the input and output circuit devices. The coupling capacitor is used to reduce an influence of jitter caused by a potential difference between a voltage at an input side circuit device sending the differential signal and a voltage at an output side circuit device receiving the differential signal. The coupling capacitor is inserted in a differential signal transmission line connecting between the foregoing output and input side circuit devices. Conventionally, the foregoing coupling capacitor (pair) is inserted in the differential signal transmission line (pair) formed on a circuit board mounted with the foregoing input and output side circuit devices. In an actual high-speed bus interface circuit, many differential signal transmission lines (pairs) are arrayed on the circuit board. Each of the differential signal transmission lines (pairs) is provided with the coupling capacitor (pair). For this reason, the mounting area on the circuit board occupied by the differential signal lines is a factor of blocking the requirements of high density wiring and high density mounting. In particular, this kind of high-speed bus interface circuit using the differential signal requires an isometric wiring technique to prevent jitter caused by a transmission delay. For this reason, differential signal wiring must be carried out under strictly limited condition. This problem is further remarkable with respect to the foregoing requirements. In addition, this kind of high-speed bus interface circuit using the differential signal employs a plurality of lanes (transmitting/receiving) configuration. Further, an isometric wiring technique is required in every lane or line pair. For this reason, the differential signal interface configuration becomes remarkably complicated. As a result, a work load of a pattern design of a printed wiring board is very high, and there is a problem to achieve high density and miniaturization of the printed wiring board.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a top plan view showing the configuration of a semiconductor package according to a first embodiment of the present invention;

FIG. 2 is a side view showing the structure of the semiconductor package according to the first embodiment;

FIG. 3 is an enlarged side view showing a part of the semiconductor package according to the first embodiment;

FIG. 4 is a circuit diagram showing a circuit connection of the semiconductor package according to the first embodiment;

FIG. 5 is a top plan view showing another configuration of the semiconductor package according to the first embodiment;

FIG. 6 is a top plan view showing a printed wiring board structure according to a second embodiment of the present invention; and

FIG. 7 is a side view showing the structure of an electronic apparatus according to a third embodiment of the present invention.

### DETAILED DESCRIPTION

Various embodiments according to the present invention will be hereinafter described with reference to accompanying drawings. In general, according to one embodiment of the present invention, there is provided a semiconductor package comprising: a substrate having one surface mounted with a semiconductor chip, and the other surface mounted with a plurality of arrayed external connection electrodes; a differential line pair provided on the surface of the substrate mounted with the semiconductor chip for connecting the semiconductor chip and a predetermined pair of electrodes included in the external connection electrodes; and a coupling capacitor pair inserted in the differential line pair.

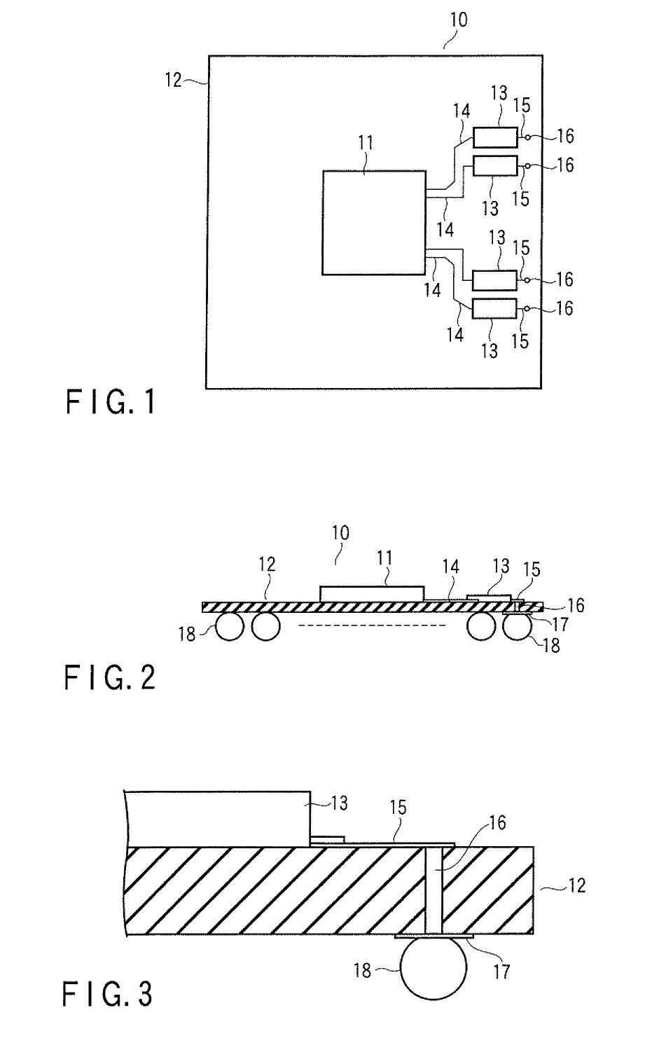

FIGS. 1 to 3 show the configuration of a semiconductor package according to a first embodiment of the present invention. FIG. 1 is a top plan view showing a semiconductor package. FIG. 2 is a side view showing the semiconductor package. FIG. 3 is a side view enlarging a jointed portion. In the first embodiment shown in FIG. 1 to FIG. 3, a ball grid array (BGA) component is given as one example of the semiconductor package.

A semiconductor package (hereinafter, referred to as BGA component) 10 according to the first embodiment of the present invention is composed of a substrate 12, a plurality of pairs of the differential lines 14, a plurality of pairs of the differential lines 15 and a plurality of pairs of the coupling capacitors 13. More specifically, the substrate 12 has one surface (front surface) mounted with a semiconductor chip (die) 11 handling a differential signal. The substrate 12 further has the other surface (back surface) mounted with a plurality of arrayed solder balls 18, 18, . . . , 18 functioning as external connection electrodes. The pairs of differential lines 14 and 15 are formed on the surface of the substrate 12, and make a connection between the semiconductor chip 11 and a predetermined pair of solder balls 18. The pair of coupling capacitors 13 is interposed between the differential lines 14 and 15.

As shown in FIG. 1 and FIG. 2, the substrate 12 comprises a rectangular plate-like substrate. The substrate 12 is mounted with the semiconductor chip 11 called as a die on the approximately center portion on the surface of the substrate 12. The semiconductor chip 11 has several pairs of differential circuits connected to the differential lines formed on the substrate 12.

The surface (front surface) of the substrate 12 mounted with the semiconductor chip 11 is formed with a wiring (interconnection) pattern. The wiring pattern is used for connecting connection terminals of the differential circuit built in the semiconductor chip 11 to the solder balls 18 mounted on the back surface of the substrate 12 and functioning as external connection electrodes. The wiring pattern is composed of the differential lines 14 and 15. The differential lines 14 make a connection between differential circuit terminals of the semiconductor chip 11 and the terminals of the coupling capacitors 13 at one end. The differential lines 15 make a connection between the solder balls 18 and the terminals of the coupling capacitors 13 at the other end.

A differential signal transmission path is composed of differential lines 14, 15 and the coupling capacitors 13. In this case, two transmission lines are formed as one pair. The paired two transmission lines are configured as a signal line synchronous with a high speed clock. Thus, the line length is set to operate within a predetermined limited error range in order to reduce jitter by transmission delay. In other words, the length of the paired two transmission lines is adjusted within a predetermined limited error range, and thus, substantial isometric wiring is achieved.

The surface (front surface) of the substrate 12 mounted with the semiconductor chip 11 is provided with a plurality of arrayed pairs of coupling capacitors 13. In this case, the coupling capacitors 13 are provided around the semiconductor chip 11 as a unit of pairs in compliance with the rule of the foregoing isometric wiring. In FIG. 1, some pairs of coupling capacitors 13, 13, . . . are arranged along one side edge of the substrate 12. For example, the mounting area of the coupling capacitors 13 is as follows. The size is 1 mm×0.5 mm, or 0.6 mm×0.3 mm or 0.4 mm×0.2 mm per one coupling capacitor 13. According to a high-speed bus configuration using a differential signal, for example, if 16-lane configuration is given, 16 pairs (32 differential lines) of transmission path and 16 pairs (32 differential lines) of reception path are provided, and 64 coupling capacitors 13 are arranged on the substrate 12.

As seen from FIG. 3, the other terminal of the differential line 15 having one terminal connected to the coupling capacitor 13 is connected to a joint portion 17 mounted with the solder ball 18 via an interlayer through via 16 including a pad 17a for connecting the via 16 and the solder ball 18.

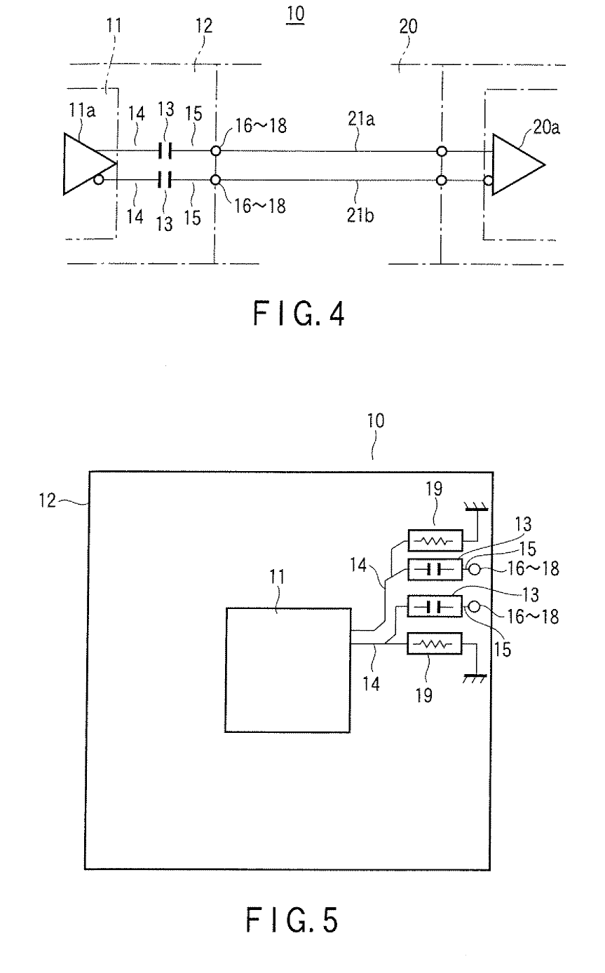

FIG. 4 shows the configuration of a differential circuit (between a driver and a receiver) when the BGA component 10 having the foregoing structure is mounted on a printed wiring board 20. The BGA component 10 having the foregoing structure is mounted on the printed wiring board 20 to achieve circuit wiring, and thereby, the following advantage is obtained. Specifically, there is no need of providing coupling capacitors for cutting a direct current component on a pair of differential wiring pattern conductors 21a, 21b formed on the printed wiring board 20. The capacitors 13 are provided between the lines 14 and 15 in the BGA component 10. Therefore, the isometric wiring of the differential wiring pattern conductors 21a, 21b is relatively easily enabled. In FIG. 4, a reference numeral 11a denotes a driver element in the differential circuit built in the semiconductor chip 11 while reference numeral 20a denotes a receiver provided in the printed wiring board 20 connected with the driver 11a through the conductors 21a, 21b, via conductors 18, pads 17a, vias 16, lines 15, capacitors 13 and lines 14.

As described above, according to the first embodiment of the present invention, the BGA component 10 has the following configuration. Specifically, the substrate 12 is provided with the coupling capacitor 13, which cuts a direct current component to prevent jitter caused by a potential difference between differential circuits (driver-receiver). In addition, the isometric wiring of the paired differential lines 14 and 15 formed via the coupling capacitors 13 on the substrate 12 is achieved. Thus, there is no need of providing a wiring structure for inserting the coupling capacitors on a differential wiring pattern conductors 21a, 21b in the printed wiring board (or circuit board) 20 mounted with the BGA component 10. Therefore, this serves to simplify a pattern design of a printed wiring board, and to achieve high density wiring, high density mounting and miniaturization of the printed wiring board. In particular, this kind of high-speed bus interface circuit using a differential signal employs the configuration of a plurality of lanes (transmitting/receiving) as described above. In addition, an isometric wiring technique is required every lane or paired lines in the conventional printed wiring board structure, thereby resulting a problem that the differential signal interface configuration becomes remarkably complicated. However, according to the first embodiment, it is possible to solve the foregoing problem, and to easily achieve simplification of a pattern design, high density and miniaturization in a printed wiring board. For example, in a high-speed bus interface such as PCI-Express and SATA (Serial-ATA), 16-lane configuration high-speed bus interface is built up. In the conventional case, 64 coupling capacitors 13 and 64 differential lines (isometric wiring) are required, whereby the interface configuration is remarkably troublesome. However, the first embodiment of the present invention largely contributes to solving the foregoing problem.

FIG. 5 shows another configuration of the BGA component 10 according to the first embodiment of the present invention. The BGA component 10 shown in FIG. 5 has the following configuration. Each differential transmission terminal is further provided with a transmission terminating resistance (resistor) 19 on a substrate 12 in addition to a coupling capacitor 13. The resistor 19 is connected between the differential line 14 and a ground potential. The foregoing configuration is provided, and thereby, it is possible to perform high density wiring and high density mounting of a printed wiring board (circuit board) mounted with the BGA component 10.

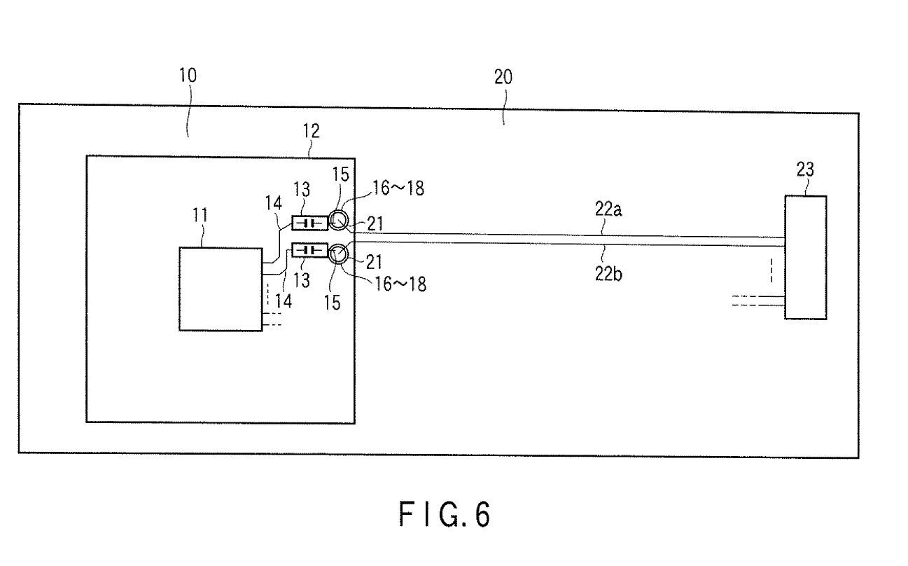

FIG. 6 shows a printed wiring board structure according to a second embodiment of the present invention.

As shown in FIG. 6, according to the second embodiment of the present invention, the printed wiring board structure is composed of a printed wiring board 20 and a BGA component 10. More specifically, the printed wiring board 20 is used as a target for mounting the BGA component 10. The BGA component 10 is mounted on a component mounting surface of the printed wiring board 20. The BGA component 10 has a structure similar to that shown in FIGS. 1-3 and the structure of the BGA component 10 shown in FIG. 6 will be explained by referring to FIGS. 2 and 3.

The BGA component 10 is composed of a substrate 12, pairs of differential lines 14, pairs of differential lines 15 and pairs of coupling capacitors 13. More specifically, the substrate 12 has a front surface mounted with a semiconductor chip (die) 11 using a differential signal, and has a back surface to which a plurality of arrayed solder balls 18 each functioning as an external connection electrode is attached. The paired differential lines 14 and 15 are formed on the substrate 12 and make a connection between the semiconductor chip 11 and a predetermined pair of solder balls 18. The coupling capacitors 13 are inserted between the differential lines 14 and 15. One terminal of the differential line 15 having the other terminal connected with the coupling capacitor 13 is connected to a joint portion 17 mounted with the solder ball 18 via an interlayer through via 16 including a pad 17a.

The printed wiring board 20 is provided with a connector 23 and a pair of differential wiring pattern conductors 22a, 22b. More specifically, the connector 23 functions as a differential circuit component, and handles a differential signal. The paired differential wiring patterns 22a, 22b each has one terminal jointed to the paired solder balls 18 of the BGA component 10 and the other terminal connected to a terminal of the connector 23.

A component mounting surface of the printed wiring board 20 is mounted with the BGA component 10. The solder balls 18 of the BGA component 10 are soldered to one terminal of the differential wiring pattern conductors 22a, 22b. The differential circuit built in the semiconductor chip 11 of the BGA component 10 and the connector handling a differential signal are connected with each other via the foregoing differential lines 14, coupling capacitors 13, differential lines 15, interlayer through vias 16, connection pads 17a, solder balls 18 and differential wiring pattern conductors 22a, 22b, which are arranged on the substrate 12 and a surface of the printed wiring board 20.

The printed wiring board structure shown in FIG. 6 has the following advantage. Specifically, there is no need of providing coupling capacitors for cutting a direct current component on the paired differential wiring pattern conductors 22a, 22b formed on the printed wiring board 20. Therefore, the isometric wiring of the differential wiring pattern conductors 22a, 22b is relatively easily achieved. In addition, there is no need of providing coupling capacitors on the printed wiring board 20. This serves to achieve high density wiring, high density mounting and miniaturization of the printed wiring board. According to the configuration shown in FIG. 6, the connector 23 handling a differential signal is given as one example of a differential circuit component connected to the BGA component 10. Other differential circuit components such as BGA components configuring a chip set with the BGA component 10 may be used.

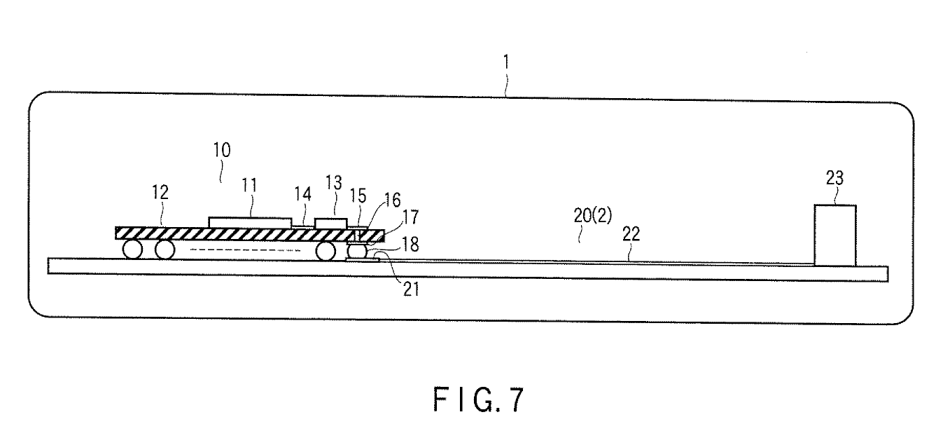

FIG. 7 shows the structure of an electronic apparatus according to a third embodiment of the present invention.

The electronic apparatus shown in FIG. 7 is composed of an electronic apparatus housing 1 and a circuit board 2 received in the electronic apparatus housing 1. The circuit board 2 received in the electronic apparatus housing 1 is realized using the printed wiring board structure 20 shown in FIG. 6. The circuit board 2 is composed of a BGA component 10 and a printed wiring board 20 mounted with the BGA component 10. The foregoing BGA component 10 has the same configuration as described in the first embodiment. Specifically, the BGA component 10 is composed of a substrate 12, pairs of differential lines 14, pairs of differential lines 15 and pairs of coupling capacitors 13. More specifically, the substrate 12 has a front surface mounted with a semiconductor chip 11 handling a differential signal. The substrate 12 further has a back surface mounted with a plurality of arrayed solder balls 18, 18, . . . , 18 functioning as external connection electrodes. The pairs of differential lines 14 and 15 are formed on the surface of the substrate 12, and make a connection between the semiconductor chip 11 and a predetermined pair of solder balls 18. The pair of coupling capacitor 13 is interposed between the paired differential lines 14 and 15. In addition, the printed wiring board 20 mounted with the BGA component 10 has the same configuration as described in the second embodiment. A component mounting surface of the printed wiring board 20 is mounted with the BGA component 10. The solder balls 18 of the BGA component are soldered to paired terminals of the differential wiring pattern conductors 22a, 22b. The differential circuit built in the semiconductor chip 11 of the BGA component 10 and the connector 23 handling a differential signal are connected via paired differential lines 14, paired coupling capacitors 13, paired differential lines 15, paired interlayer through vias 16, paired joint portions or pads 17, paired solder balls 18 and paired differential wiring pattern conductors 22a, 22b, which are arranged on the substrate 12 except for the conductors 22a, 22b.

The circuit board 2 configured using the printed wiring board 20 does not requires coupling capacitors on the differential signal transmission path on the circuit board 2. Therefore, it is possible to provide an electronic apparatus 1, which can achieve high density and miniaturization at low cost.

According to the foregoing embodiments, the BOA component 10 is given as an example of the semiconductor package, however, the present invention is not limited to the BGA component. For example, the foregoing embodiments of the present invention are applicable to an area array type semiconductor package such as land grid array (LGA) and pin grid array (PGA).

While certain embodiments of the invention have been described, there embodiments have been presented by way of example only, and are not intended to limit the scope of the invention. Indeed, the novel methods and systems described herein may be embodied in a variety of other forms; furthermore, various omissions, substitutions and changes in the form of the methods and systems described herein may be made without departing from the spirit of the invention. The accompanying claims and their equivalents are intended to cover such forms or modifications as would fall within the scope and spirit of the invention.

What is claimed is:

1. A semiconductor package comprising:
a substrate having one surface mounted with a semiconductor chip, and the other surface mounted with a plurality of arrayed external connection electrodes;
a differential line pair provided on the surface of the substrate mounted with the semiconductor chip, and making a connection between the semiconductor chip and a predetermined pair of electrodes included in the external connection electrodes; and
a coupling capacitor pair inserted between the differential lines.

2. The semiconductor package according to claim 1, wherein a plurality of the differential line pairs and the coupling capacitor pairs are provided on the surface of the substrate mounted with the semiconductor chip.

3. The semiconductor package according to claim 1, wherein the surface of the substrate mounted with the semiconductor chip is provided with a plurality of termination resistance elements each connected to each of the coupling capacitor pair.

4. The semiconductor package according to claim 2, wherein the differential lines pair and the coupling capacitors pair form a differential transmission lines of a serial transmission path type.

5. The semiconductor package according to claim 4, wherein the differential lines pair and the coupling capacitors pair form a high-speed serial bus.

6. The semiconductor package according to claim 5, wherein isometric wiring of the differential lines pair connected with the coupling capacitors pair is configured to operate within a predetermined limited error range on the substrate.

7. A printed wiring board structure comprising:
a semiconductor package including:
a substrate having one surface mounted with a semiconductor chip, and the other surface mounted with a plurality of arrayed external connection electrodes;
a differential lines pair provided on the surface of the substrate mounted with the semiconductor chip, and making a connection between the semiconductor chip and a predetermined pair of electrodes included in the external connection electrodes; and
a coupling capacitors pair inserted between the differential lines; and
a printed wiring board having a mounting surface mounted with the semiconductor package, and provided with a differential wiring pattern conductors pair connected to the pair of electrodes,
wherein the mounting surface of the printed wiring board is mounted with the semiconductor package, and the pair of electrodes is connected to the differential wiring pattern conductors pair, thereby the differential wiring pattern conductors pair being connected to the semiconductor chip via the coupling capacitors pair.

8. An electronic apparatus comprising:
an electronic apparatus main body; and
a circuit board built in the electronic apparatus main body,
wherein the circuit board includes:
a substrate having one surface mounted with a semiconductor chip, and the other surface mounted with a plurality of arrayed external connection electrodes;
a differential lines pair provided on the surface of the substrate mounted with the semiconductor chip, and making a connection between the semiconductor chip and a predetermined pair of electrodes included in the external connection electrodes; and
a coupling capacitors pair inserted between the differential lines; and
a printed wiring board having a mounting surface mounted with the semiconductor package, and provided with a differential wiring pattern conductors pair connected to the pair of electrodes,
the mounting surface of the printed wiring board being mounted with the semiconductor package, and the pair of electrodes being connected to the differential wiring pattern conductors pair, thereby the differential wiring pattern conductors pair being connected to the semiconductor chip via the coupling capacitors pair.
